(19) United States
(12) Patent Application Publication
(10) Pub. No.: US 2024/0096981 A1
(43) Pub. Date: Mar. 21, 2024

(54) THREE-DIMENSIONAL SOURCE CONTACT STRUCTURE AND FABRICATION PROCESS METHOD OF MAKING THE SAME

(71) Applicant: National Yang Ming Chiao Tung University, Hsinchu City (TW)

(72) Inventors: Bing-Yue Tsui, Hsinchu City (TW); Jui-Cheng Wang, Hsinchu City (TW); Li-Tien Hsueh, Taipei City (TW); Jui-Tse Hsiao, Taichung City (TW)

(73) Assignee: National Yang Ming Chiao Tung University, Hsinchu City (TW)

(21) Appl. No.: 18/098,760

(22) Filed: Jan. 19, 2023

(30) Foreign Application Priority Data
Sep. 15, 2022 (TW) 111134908

(51) Int. Cl. H01L 29/417; H01L 29/16; H01L 29/40; H01L 29/45; H01L 29/66

(52) U.S. Cl. CPC H01L 29/41741; H01L 29/1608; H01L 29/401; H01L 29/45; H01L 29/66068; H01L 29/6656

(57) ABSTRACT

A three-dimensional source contact structure and its fabrication process method thereof are applicable to a power device, in which an inter-layer dielectric is deposited thereon. A lithography process is applied for forming a first and second dielectric layer. A spacer is respectively provided on opposite sidewalls of the first and second dielectric layer. And a shallow trench process is sequentially performed along the opposite surfaces of the spacers. The spacers are removed after the shallow trench process is complete for exposing a first and a second metal-source surface contact region. The present invention achieves in increasing horizontal surface contact and longitudinal vertical contact when depositing a source contact metal, thereby a step-like three-dimensional source contact structure can be formed. By employing the present invention, it enhances to reduce cell pitch effectively and can be widely applied to various power devices having MOSFET structure thereof.

This application claims priority of Application No. 111134908 filed in Taiwan on 15 Sep. 2022 under 35 U.S.C. § 119; the entire contents of all of which are hereby incorporated by reference.

### BACKGROUND OF THE INVENTION

### Field of the Invention

The present invention is related to a source contact structure and its fabrication method. More particularly, it is related to a three-dimensional source contact structure and its fabrication process method of making the same, in which the silicon carbide shallow trench process in the metal contact window is employed such that vertical metal contact can be increased.

### Description of the Prior Art

As known, high-power Metal Oxide Semiconductor Field Effect Transistors (MOSFET) according to different channel types, mainly include: Vertical Double Diffused Metal Oxide Semiconductor Field Effect Transistors (VDMOSFET) with a planar channel, and U-shaped Metal Oxide Semiconductor Field Effect Transistors (UMOSFET) with a vertical channel. In general, it is better for the high-power devices to have a smaller on-resistance. As the device area becomes larger, the on-resistance can be reduced. However, it should be noticed that under the condition of achieving the same on-state current, a larger device area also increases its fabrication cost. Therefore, to properly evaluate the on-resistance of a power device, it is fairly determined on a basis of the “resistance per unit area”, which is also known as the specific on-resistance R_{on,sp} (ohm-cm²). It is believed that a lower specific on-resistance R_{on,sp} indicates that the device performance is more superior.

And in order to obtain a high on-state current, it is more likely to parallelly connect a large number of transistors in a power device. Please find FIG. 1 of the present invention for references, in which a less length of the cell pitch 11 is believed to be able to increase the density of per unit area, thereby reducing the specific on-resistance R_{on,sp} (ohm-cm²). As a result, it is apparent that one major technique for reducing the specific on-resistance R_{on,sp} (ohm-cm²) of a high power device mainly lies in effectively shortening the cell pitch configured therein the device.

Among the current technologies, it has been provided a plenty of methodologies for shortening the cell pitch. Taking a VDMOSFET as an illustrative example, the methods may include shortening its channel length, reducing the overlapping length of its gate and source regions, reducing the spacing between adjacent P-type bodies (P-body), reducing the width of the contact window, reducing the contact width of the P-body and metal, and reducing the contact width of the source and metal, etc. Since the contact resistance (R_{CS}) is inversely proportional to the contact area (A_{C}), a less contact width of the source and metal, on the other hand, increases the contact resistance. In addition, it is also apparent that to obtain a smaller contact window, it requires high process complexity for contact window and metal deposition fabrications. Therefore, the process complexity of the power device will be significantly increased. Based on such reasons, the above-mentioned existing methodologies are normally limited by the minimum width of the contact window, the contact resistance between the source and metal, and so on. And thus, as the device size is getting scaled down nowadays, these existing methodologies are believed as not practical and feasible anymore.

Apart from the above, it has been well known that a standard source metal contact process may be performed as follows: after all the ion implantations and gate fabrication process are completed, a dielectric layer is deposited. Later, a source contact window is formed by employing a lithography process. Subsequently, metal deposition (nickel, for example, is usually used) can be performed. After annealing at a high temperature, the metal (nickel) and silicon carbide react to form Ni-silicide. And after removing the unreacted nickel metal, a structure as illustrated in FIG. 2 of the present invention can be formed. In FIG. 2, the formed Ni-silicide 211 is depicted by a solid pattern. Furthermore, in order to ensure the isolation between the source and the gate regions, a sufficient spacing “S” between the edge of the source contact window and the gate edge must be maintained. In general, the spacing S is usually between 0.5 μm and 1.0 μm. Meanwhile, a sufficient overlapping length “O” of the contact window and the source region, as illustrated in FIG. 2, is also necessary in order to reduce the contact resistance of the source and metal. Such overlapping length O is usually between 0.5 μm and 2.0 μm. At the same time, according to the public methods which have been disclosed in the existing patents and documents, the methods for improving the source contact resistance and reducing the cell pitch are mainly performed based on the self-aligned manners for obtaining a maximum contact area on the basis of the same cell pitch. Therefore, it is believed that the spacing between the contact window and the source region will be affected by the alignment errors of two lithography processes and line widths of two lithography/etching processes. Taking FIG. 2 as the explanatory example, assume that a minimum value of the overlapping length O is 0.5 μm, and the alignment process error is 0.2 μm, then it will be required to design the overlapping length O to be at least 0.7 μm (0.5 μm+0.2 μm=0.7 μm). And yet, even by doing so, when there is an alignment process error or offset generated in the fabrication process, such that the contact areas at the left and right sides of the source region are different, it also results in unfair contact resistances and leads to uneven current distributions. Therefore, the device reliability is degraded. From this point of view, it is obvious that a series of negative effects will thus be generated. As a result, it can be observed that for the current power devices, it is severely important for those skilled in the art to find an effective and balanced methodology for reducing the cell pitch and meanwhile avoiding the above-mentioned drawbacks and negative effects to be generated.

As set forth, on account of the above, in order to overcome the above-mentioned issues, it should be apparent that there is indeed an urgent need for the professionals in the field for a new and novel process method to be developed, that can effectively solve the foregoing problems existing in the prior arts. And by employing the proposed process method, the cell pitch can be effectively reduced under the condition of the same contact area. At the same time, it is believed that the foregoing deficiencies existing in the prior arts are solved as well. Regarding the detailed specific descriptions and implementations, the Applicants of the present invention will be providing in detail in the following paragraphs as below.

### SUMMARY OF THE INVENTION

In order to overcome the above-mentioned disadvantages, one major objective in accordance with the present invention is provided for a novel process technology, which is aimed to fabricate a three-dimensional source contact structure between the metal and source region. By adopting the disclosed technical contents of the present invention, it effectively achieves in reducing the cell pitch and maintaining the same contact area at both sides of the source region. Meanwhile, a low process complexity of the disclosed process method can be obtained.

Another major objective in accordance with the present invention is to provide a three-dimensional source contact structure and its fabrication process method of making the same. According to one embodiment of the present invention, a silicon carbide shallow trench process along the metal contact window is adopted, such that the source contact metal is able to have horizontal surface contact along the silicon carbide surface. And apart from the horizontal surface contact, longitudinal vertical contact of the source contact metal can be obtained as well. Specifically, according to the embodiment of the present invention, a spacer is respectively provided on opposite sidewall of the dielectric layer. And a shallow trench process is sequentially performed along the opposite surfaces of the two spacers, such that the formed metal contact window can be extending downwardly. After the shallow trench process is complete, the spacers are removed, so as to expose the sufficient silicon carbide surface for increasing the horizontal surface contact when subsequent source metal deposition is performed.

Therefore, on account of the formation of the above-mentioned horizontal surface contact and longitudinal vertical contact, the present invention successfully achieves in designing the source contact metal in a step-like three-dimensional structure. By applying the proposed technical contents of the present invention to a power device having a Vertical Double Diffused Metal Oxide Semiconductor Field Effect Transistor (VDMOSFET) structure or an U-shaped Metal Oxide Semiconductor Field Effect Transistors (UMOSFET) structure, it is believed that a three-dimensional source contact structure can be formed, and a step-like three-dimensional source contact metal can be deposited and obtained.

And furthermore, when employing the disclosed three-dimensional source contact structure and its fabrication process method thereof the present invention, it is also believed that aspect ratio of the metal contact window can be reduced, which is beneficial to the subsequent metal deposition process. Moreover, the proposed technical contents of the present invention can be widely applied to any power transistor which includes the Vertical Double Diffused Metal Oxide Semiconductor Field Effect Transistor (VDMOSFET) structure or the U-shaped Metal Oxide Semiconductor Field Effect Transistors (UMOSFET) structure. And even more, it is believed that a variety of power devices which include the MOSFET structures at its top surface may even be applied thereto as well.

And yet, apart from the above, still one major objective of the present invention is to provide a stereoscopic three-dimensional source contact structure and its fabrication process techniques thereof. In view of the process techniques, the shallow trench process is provided and performed along the opposite surfaces of the foregoing mentioned two spacers such that the formed metal contact window can be extending downwardly. As a result, a larger pattern area of the contact window can be achieved by utilizing the present invention. In addition, it is also beneficial to the following contact window lithography process.

Therefore, for achieving the above-mentioned objectives, the proposed three-dimensional source contact structure of the present invention is applicable to a power device, wherein the power device includes a semiconductor substrate, and an epitaxial layer and a body region are sequentially formed on the semiconductor substrate. The proposed three-dimensional source contact structure comprises: a source heavily doped area configured on the body region, wherein a metal contact window is formed in the source heavily doped area, such that the source heavily doped area is divided by the metal contact window into a first heavily doped region and a second heavily doped region formed on opposite sides of the metal contact window. An inter-layer dielectric is configured on the source heavily doped area, wherein the inter-layer dielectric is also divided by the metal contact window into a first dielectric layer and a second dielectric layer formed on opposite sides of the metal contact window. The first dielectric layer is disposed on the first heavily doped region. The second dielectric layer is disposed on the second heavily doped region. And a contact length of the first dielectric layer and the first heavily doped region is less than a length of the first heavily doped region such that a first metal-source surface contact region is exposed. In addition, a contact length of the second dielectric layer and the second heavily doped region is less than a length of the second heavily doped region such that a second metal-source surface contact region is exposed.

Subsequently, a source contact metal is thus being deposited between the first dielectric layer and the second dielectric layer, between the first heavily doped region and the second heavily doped region, and on the body region though the metal contact window. The source contact metal covers at least the foregoing first metal-source surface contact region, the second metal-source surface contact region, a longitudinal surface along the first heavily doped region and the second heavily doped region, and an interval surface between the first heavily doped region and the second heavily doped region, such that the source contact metal has a step-like three-dimensional structure.

According to the embodiment of the present invention, the semiconductor substrate of the power device, for instance, can be made of silicon (Si), silicon carbide (SiC), gallium oxide (Ga₂O₃), aluminum nitride (AlN), or diamond. And a material of the formed source contact metal may comprise Ni-silicide.

According to the embodiment of the present invention, a length of the exposed first metal-source surface contact region and the second metal-source surface contact region is, for instance, between 0.2 μm and 1.0 μm. As for the exposed longitudinal surface, a depth of the longitudinal surface along the first heavily doped region and the second heavily doped region, for instance, can be between 0.2 μm and 0.5 μm. Generally evaluating, according to the three-dimensional source contact structure disclosed in the present invention, it is obvious that it can certainly be applied to a Vertical Double Diffused Metal Oxide Semiconductor Field Effect Transistor (VDMOSFET) structure or an U-shaped Metal Oxide Semiconductor Field Effect Transistor (UMOSFET) structure. Alternatively, it can be further widely applied to any power transistor which includes the VDMOSFET or the UMOSFET structure, for example, an Insulated Gate Bipolar Transistor (IGBT). Overall, for people who are skilled in the art and having ordinary knowledge, appropriate modifications or changes based on the technical solutions disclosed in the present invention without departing from the spirit of the present invention are practicable. However, the modifications should still fall into the scope of the present invention. The present invention is certainly not limited thereto the disclosed parameters, conditions, as well as fields of the application.

In another aspect, the present invention also discloses a fabrication process method of making the three-dimensional source contact structure, and the fabrication process method includes a plurality of steps as follows. A power device is firstly provided, which includes the semiconductor substrate, and the epitaxial layer and the body region are sequentially formed on the semiconductor substrate. Later, a source heavily doped area is formed on the body region, wherein a third heavily doped region is buried in the body region, and the third heavily doped region is configured and isolated in the source heavily doped area. Subsequently, an inter-layer dielectric is deposited on the source heavily doped area, and a lithography process is performed to form the metal contact window therein. The metal contact window divides the inter-layer dielectric into a first dielectric layer and a second dielectric layer formed on opposite sides of the metal contact window. According to the embodiment of the present invention, each of the first dielectric layer and the second dielectric layer is formed in a rectangle shape.

And then, the present invention proceeds to provide a spacer respectively on opposite sidewalls of the first dielectric layer and the second dielectric layer, and a shallow trench process along opposite surfaces of two of the spacers is performed so that the metal contact window extends downwardly. According to the embodiment of the present invention, the proposed shallow trench process for instance, can be performed by adopting a plasma etching process. As for the disclosed spacer, a thickness of the spacer, may be between 0.2 μm and 1.0 μm. And, a material of the spacer, for instance, can be silicon nitride (Si₃N₄), silicon dioxide (SiO₂), nickel (Ni), or a material not removable when performing the shallow trench process.

At this time, on account of the downwardly extending metal contact window and the shallow trench process, the present invention is able to divide the source heavily doped area into the first heavily doped region and the second heavily doped region formed on opposite sides of the metal contact window. Meanwhile, the longitudinal surface along the first heavily doped region and the second heavily doped region, and the interval surface between the first heavily doped region and the second heavily doped region are exposed. In general, an etching depth of the shallow trench process performed in the present invention, is not less than a thickness of the first heavily doped region and the second heavily doped region, such that the longitudinal surface having sufficient depth along the first heavily doped region and the second heavily doped region can be obtained and exposed. Overall, generally according to the three-dimensional source contact structure and the fabrication process method for forming the structure disclosed in the present invention, a depth of the longitudinal surface along the first heavily doped region and the second heavily doped region, for instance, can be between 0.2 μm and 0.5 μm.

Later, after the above-mentioned shallow trench process is complete, the present invention proceeds to remove the previously used spacers. According to one embodiment of the present invention, the spacers, for instance, can be removed by using hot phosphoric acid (H₃PO₄). In one embodiment, the hot phosphoric acid (H₃PO₄) is used for removing the spacers when the spacers are made of silicon nitride (Si₃N₄). In alternative embodiments, when the spacers are made of other materials, then alternative removing agent can be adopted for removing the spacers. Therefore, after the spacers are removed, it is apparent that the first metal-source surface contact region and the second metal-source surface contact region will be exposed. As a result, on the basis of such structure, the present invention is able to perform the subsequent source contact metal deposition process such that the source contact metal is deposited between the first dielectric layer and the second dielectric layer, between the first heavily doped region and the second heavily doped region, and on the body region. At this time, it is believed that the source contact metal covers at least the first metal-source surface contact region, the second metal-source surface contact region, the longitudinal surface along the first heavily doped region and the second heavily doped region, and the interval surface between the first heavily doped region and the second heavily doped region, such that the source contact metal formed by the present invention, has the step-like three-dimensional structure.

Furthermore, according to the process technology disclosed in the present invention, the above-mentioned semiconductor substrate, the epitaxial layer, the first heavily doped region and the second heavily doped region have a first semiconductor type. And the body region and the third heavily doped region have a second semiconductor type. And the first semiconductor type and the second semiconductor type are opposite conductivity types. In other words, the present invention is not limited to an N-type or P-type conductivity type. According to the disclosed technique characteristics proposed in the present invention, regarding the following embodiments provided by the present invention disclosed by the Applicants, an N-type silicon carbide is simply used as an illustrative example to implement the semiconductor substrate of the present invention for introducing the technical spirits of the invention. As a result, it is aimed to enable those skilled in the art to fully understand the technical solution of the present invention, and yet not to limit the application of the present invention. In other words, according to the process method disclosed in the present invention, its application field is certainly not limited to the N-type silicon carbide substrate but can also be widely applied to a variety of semiconductor substrates, including transistors with an N-type channel or a P-type channel. Also, substrates made of various semiconductor materials, such as silicon (Si), gallium oxide (Ga₂O₃), aluminum nitride (AlN), and diamond, etc. are applicable as well.

And yet, moreover, according to the embodiment of the present invention, a length of the exposed first metal-source surface contact region and the second metal-source surface contact region is, for instance, between 0.2 μm and 1.0 μm. Preferably, the length can be 0.3 μm. As for the exposed longitudinal surface, a depth of the longitudinal surface along the first heavily doped region and the second heavily doped region, for instance, can be between 0.2 μm and 0.5 μm. In general, the etching depth of the shallow trench process performed in the present invention, is not less than a thickness of the first heavily doped region and the second heavily doped region, such that the longitudinal surface having sufficient depth along the first heavily doped region and the second heavily doped region can be obtained and exposed. Overall, generally according to the three-dimensional source contact structure and the fabrication process method for forming the structure disclosed in the present invention, appropriate modifications or variant adjustments are allowed to be made by those skilled in the art and having ordinary knowledge without departing from the spirit of the present invention. Nevertheless, the above-mentioned modifications or variant adjustments should still belong to the claimed scope of the present invention. The present invention is certainly not limited to the disclosed process parameters or their process conditions since the present invention is characterized by having superior process flexibility.

Therefore, to sum up, it is apparent that the present invention discloses a novel process method for achieving a three-dimensional source contact structure. In view of the disclosed process method, the present invention achieves in obtaining the purposes of effectively reducing the cell pitch under the same contact area. At the same time, it also maintains the same contact area at the left and right side of the source region and reduces the process complexity.

In addition, since the disclosed three-dimensional source contact structure and its fabrication process method provided by the present invention can be effectively applied to any power devices having not only the VDMOSFET, UMOSFET, or IGBT structure, but a variety of power devices also having MOSFET structure on its top surface may be applied thereto as well. As such, it is believed that when adopting the process techniques of the present invention, a source contact metal having the step-like three-dimensional structure can be formed, such that a horizontal surface contact and longitudinal vertical contact of depositing a source contact metal can be accomplished as a superior result.

Below, the embodiments are described in detail in cooperation with the drawings, so that these and other objectives of the present invention will become obvious to those of ordinary skill in the art after reading the following detailed description of preferred embodiments. And technical contents, characteristics and accomplishments of the invention are easily comprehensive.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 schematically shows a structural diagram corresponding to a standard source contact metal process used in the prior art.

FIG. 2 schematically shows a structural diagram from FIG. 1 in which a Ni-silicide is deposited thereon.

FIG. 3 schematically shows a structural diagram illustrating a source contact region where the modifications of the present invention are configured therein.

FIG. 4 schematically shows a structural diagram of a three-dimensional source contact structure in accordance with one embodiment of the present invention.

FIG. 5 schematically shows a structural diagram from FIG. 4 in which a source contact metal is deposited.

FIG. 6 shows a process flow chart illustrating the steps of the proposed fabrication process method of making the three-dimensional source contact structure in accordance with the embodiment of the present invention.

FIG. 7 schematically shows a structural diagram in relative to the proposed fabrication process method in accordance with the embodiment of the present invention.

FIG. 8 schematically shows a structural diagram from FIG. 7 in which a lithography process is performed.

FIG. 9 schematically shows a structural diagram from FIG. 8 in which spacers are provided therein.

FIG. 10 schematically shows a structural diagram from FIG. 9 in which a shallow trench process is performed.

FIG. 11 schematically shows a structural diagram from FIG. 10 in which the spacers are removed so as to expose the metal-source surface contact regions.

FIG. 12 schematically shows a structural diagram from FIG. 11 in which a source contact metal is deposited thereon.

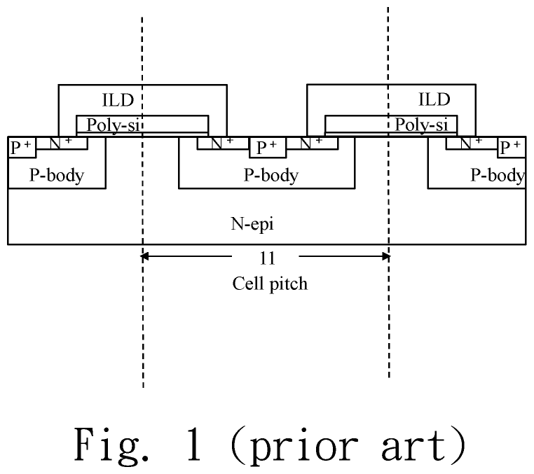

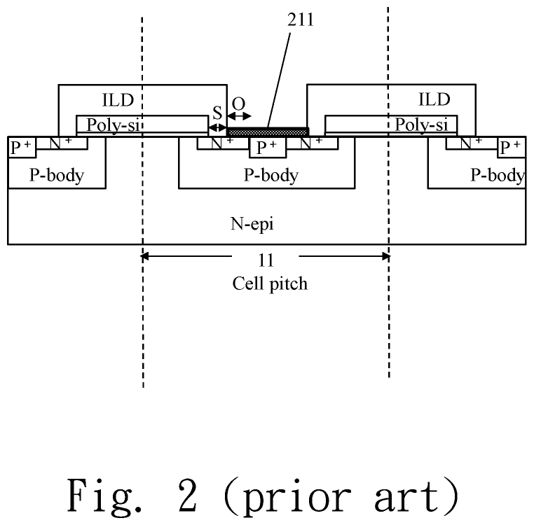

### DESCRIPTION OF THE PREFERRED EMBODIMENTS

It is to be understood that both the foregoing general description and the following detailed description are exemplary and are intended to provide further explanation of the invention as claimed.

Reference will now be made in detail to the preferred embodiments of the present invention, examples of which are illustrated in the accompanying drawings. Wherever possible, the same reference numbers are used in the drawings and the description to refer to the same or like parts.

The embodiments described below are illustrated to demonstrate the technical contents and characteristics of the present invention and to enable the persons skilled in the art to understand, make, and use the present invention. However, it shall be noticed that, it is not intended to limit the scope of the present invention. Therefore, any equivalent modification or variation according to the spirit of the present invention is to be also included within the scope of the present invention.

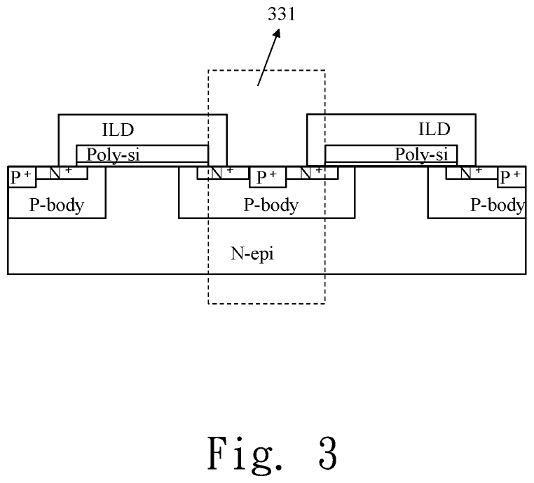

The present invention discloses a three-dimensional source contact structure, which is aimed to improve and modify the current contact structure between the source region and metal. One objective of the present invention is to effectively reduce the device cell pitch under the condition of maintaining the same contact area. Meanwhile, contact areas at the left and right sides of the source region can be controlled to have the same area by utilizing a less process complexity manner, thereby making the present invention inventive and advantageous. Since the main technical spirits and solutions are provided based on the source contact structure and its fabrication process method thereof, the rest ion implantation and gate fabrication processes of the transistor are known as being similar to the current standard processes. As such, the similar descriptions are omitted in the present invention, and the applicants of the present invention merely provide detailed descriptions regarding the source contact region 331 where the modifications are made, as illustrated in FIG. 3 for your references.

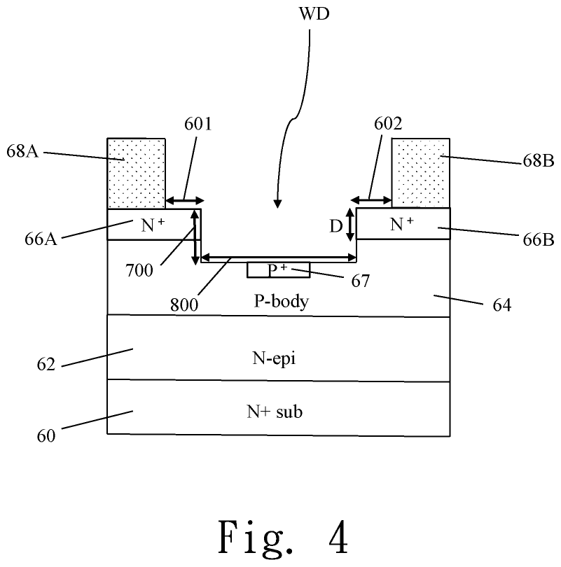

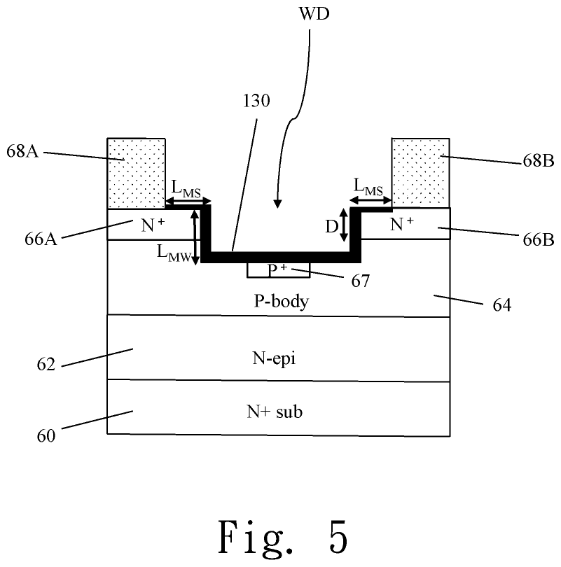

Please refer to FIG. 4 and FIG. 5, which schematically show a structural diagram of a three-dimensional source contact structure in accordance with one embodiment of the present invention, respectively. Moreover, FIG. 5 schematically depicts a structural diagram from FIG. 4 in which, when a source contact metal 130 is further deposited thereon the structure. As shown in the figures, the disclosed three-dimensional source contact structure can be applied and applicable to a power device. In order to clearly and concisely describe the detailed implementations of the present invention, a basic VDMOSFET structure is used in the following descriptions as an exemplary embodiment for explaining the technical contents of the present invention. However, it should also be noted that such embodiment should not be taken for limiting the claim scope of the present invention. Within the scope of its equality, other variant modifications should still fall into the scope and claims of the present invention.

Specifically, according to the embodiment of the present invention, the disclosed power device includes a semiconductor substrate 60, and an epitaxial layer 62 is formed on the semiconductor substrate 60. Subsequently, a body region 64 is further configured on the epitaxial layer 62. In one preferable embodiment of the present invention, the semiconductor substrate 60 can be a substrate made of N-type heavily doped silicon carbide (shown as “N+sub” in the figures). And the epitaxial layer 62 (shown as “N-epi” in the figures) can be preferably an N-type SiC (silicon carbide) epitaxial layer which is formed by epitaxial growth on an upper surface of the semiconductor substrate 60. A P-type body implantation process can be utilized to form the body region 64 (shown as “P-body” in the figures). It is noted that the disclosed semiconductor substrate 60 should not be limited to an N-type SiC substrate. Alternative substrates made of other semiconductor materials, such as silicon (Si), gallium oxide (Ga₂O₃), aluminum nitride (AlN), and diamond, etc. are also applicable and feasible materials for forming the disclosed semiconductor substrate 60. The detailed descriptions provided in the following paragraphs simply use the N-type silicon carbide material as an illustrative implementation embodiment. Basically, in view of the same technical manners, those skilled in the art and have common knowledge backgrounds in the technical field are allowed to apply the technical solution disclosed in the present invention to the P-type semiconductor substrate, for instance. And the present invention spares the same descriptions.

According to the embodiment of the present invention, a source heavily doped area (shown as “N+” in the figures) is configured on the body region 64. And a metal contact window WD is formed in the source heavily doped area, such that the source heavily doped area is divided by the metal contact window WD into a first heavily doped region 66A (shown as “N+” in the figures) and a second heavily doped region 66B (shown as “N+” in the figures). The first heavily doped region 66A and the second heavily doped region 66B are respectively formed on opposite sides of the metal contact window WD. In addition, a third heavily doped region 67 (shown as “P+” in the figures) is formed underneath the metal contact window WD, and the third heavily doped region 67 is buried in the foregoing body region 64. In such an embodiment, a width of the third heavily doped region 67 is designed as being narrower than a bottom width of the metal contact window WD. However, the present invention is not limited thereto. According to other practicable embodiment of the present invention, the width of the third heavily doped region 67 may also be alternatively designed as being greater than the bottom width of the metal contact window WD, for the purposes of providing a larger metal contact window and a subsequent easier lithography process of the metal contact window. The inventive effects of the present invention may also be implemented through these variant design manners.

And then, an inter-layer dielectric (shown by dotted patterns in the figures) is then further provided on the above-mentioned source heavily doped area. At the same time, the inter-layer dielectric is also divided by the metal contact window WD into a first dielectric layer 68A and a second dielectric layer 68B, which are formed on opposite sides of the metal contact window WD. As can be seen, the first dielectric layer 68A is disposed on the first heavily doped region 66A, and the second dielectric layer 68B is disposed on the second heavily doped region 66B. As illustrated in FIG. 4 and FIG. 5, it is apparent that a contact length of the first dielectric layer 68A and the first heavily doped region 66A is less than a length of the first heavily doped region 66A, such that a first metal-source surface contact region 601 is exposed. Similarly, a contact length of the second dielectric layer 68B and the second heavily doped region 66B is less than a length of the second heavily doped region 66B, such that a second metal-source surface contact region 602 is exposed as well.

By such arrangements, please refer to FIG. 5, then a source contact metal 130 can be deposited between the first dielectric layer 68A and the second dielectric layer 68B, between the first heavily doped region 66A and the second heavily doped region 66B, and on the body region 64 though the metal contact window WD. In addition, it is obvious that the source contact metal 130 covers at least the above-mentioned first metal-source surface contact region 601, the above-mentioned second metal-source surface contact region 602, a longitudinal surface 700 along the first heavily doped region 66A and the second heavily doped region 66B, and an interval surface 800 between the first heavily doped region 66A and the second heavily doped region 66B, such that the source contact metal 130 formed by the present invention has a step-like three-dimensional structure. In general, the source contact metal 130 can be formed, for example, by depositing a contact metal first, such as nickel (Ni), and annealing it at a high temperature to form nickel-silicide (Ni-silicide). After that, a selective etching process can be carried out to remove the unreacted nickel, such that the source contact metal 130 as shown in FIG. 5 can be formed. As a result, according to the embodiment of the present invention, the source contact metal 130 formed by the present invention is able to have a step-like three-dimensional structure. And after that, a variety of subsequent steps are mostly the same as the standard processes in the existing VDMOSFET fabrication process. As for the following gate contact window lithography, etching processes, as well as metal deposition and metal layer lithography processes, these processes may further be performed by those skilled in the art for the subsequent flow processes.

To be more specific, please refer to FIG. 5 for a detailed structural diagram. As can be seen, the exposed first metal-source surface contact region 601 and second metal-source surface contact region 602 has a length L_{MS}. And the length L_{MS} of the first metal-source surface contact region 601 and the second metal-source surface contact region 602 can be preferably controlled between 0.2 μm and 1.0 μm. In addition, the exposed longitudinal surface 700 along the first heavily doped region 66A and the second heavily doped region 66B has a depth L_{MW}. And the depth L_{MW} of the longitudinal surface 700 can be preferably controlled between 0.2 μm and 0.5 μm. As can be seen from such an embodiment of the present invention, each of the first dielectric layer 68A and the second dielectric layer 68B is formed in a rectangle shape.

And furthermore, according to the technical contents of the present invention, the above-mentioned length L_{MS} of the exposed first metal-source surface contact region 601 and the second metal-source surface contact region 602 is generally associated with a thickness of a spacer provided in the process parameter of the present invention (which will be discussed later in the following paragraphs). On the other hand, the depth L_{MW} of the exposed longitudinal surface 700 is associated with the process parameters of a shallow trench process performed to the source heavily doped area (N+). Normally, an etching depth of the shallow trench process is approximately close to or slightly more than (not less than) the thickness D of the first heavily doped region 66A and the second heavily doped region 66B, in order to expose a longitudinal surface 700 having sufficient depth L_{MW}. Regarding the process method for forming such structure, the applicants of the present invention will be providing in the following sections for your references.

In addition, as previously mentioned, since the present invention is aimed to provide modifications and improvements regarding the source contact region 331 as illustrated in FIG. 3, some other standard structures, such as the dielectric layer and source heavily doped area outside the source contact region or in between the first and second heavily doped regions should be well known by people skilled in the art. Since these technical contents are mostly the current standard processes and are not the main technical spirits claimed by the applicant's invention, these descriptions are not intended to be proposed herein the present invention.

And even furthermore, it should be also noted that, the present invention is not limited by the semiconductor conductivity type used in the embodiments. In other words, according to the present invention, the above-mentioned semiconductor substrate, the epitaxial layer, the first heavily doped region and the second heavily doped region of the disclosed invention have a first semiconductor type. And the body region and the third heavily doped region have a second semiconductor type. The first semiconductor type and the second semiconductor type are opposite conductivity types. Therefore, in one embodiment of the present invention, when the first semiconductor type is N type, the second semiconductor type will be P type. And in an alternative embodiment of the present invention, when the first semiconductor type is P type, then the second semiconductor type will be N type. That is to say, based on the technical solutions provided by the present invention, the disclosed three-dimensional source contact structure can be effectively formed on an N-type heavily doped substrate. And based on the same principles, the disclosed three-dimensional source contact structure may also be applicable to a P-type heavily doped substrate and formed on the P-type heavily doped substrate. The above-mentioned first and second semiconductor types are not intended to limit the claim scopes of the invention.

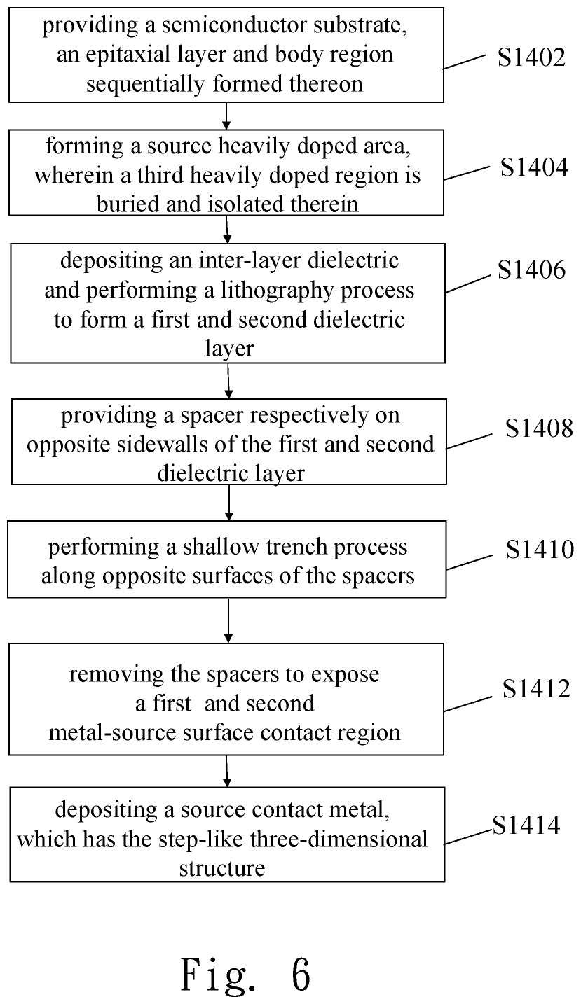

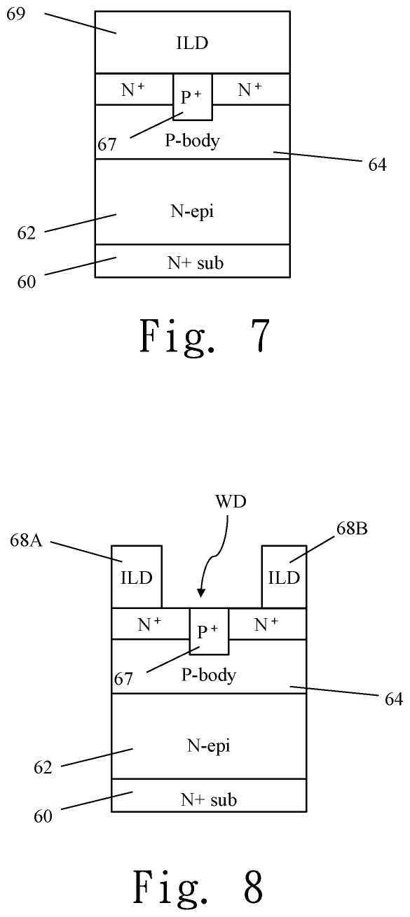

In view of the foregoing disclosed descriptions regarding the three-dimensional source contact structure formed by the present invention, hereinafter, the applicants of the present invention will be providing its fabrication process method of making the three-dimensional source contact structure in the following sections. For better comprehensive understandings of the present invention, please refer to FIG. 6 for a detailed flow chart illustrating the steps of the fabrication process method, and FIG. 7-FIG. 12 for structural diagrams relatively corresponding to each step of the proposed fabrication process method.

First, as shown in the step of S1402 in FIG. 6, the present invention provides a power device as illustrated in FIG. 7, which includes the semiconductor substrate 60, the epitaxial layer 62 and the body region 64 sequentially formed on the semiconductor substrate 60 as previously described.

Later, as shown in the step of S1404, the source heavily doped area (shown as “N+” in FIG. 7 to FIG. 9) is formed on the body region 64. And the third heavily doped region 67 is buried in the body region 64, and the third heavily doped region 67 is configured and isolated in the source heavily doped area.

And then, as shown in the step of S1406, an inter-layer dielectric is deposited on the source heavily doped area. As can be seen in FIG. 7, the inter-layer dielectric is labelled as “ILD” 69. And after that, a lithography process is performed to form the metal contact window WD, as illustrated in FIG. 8. And by the formed metal contact window WD, the inter-layer dielectric 69 is divided into the first dielectric layer 68A and the second dielectric layer 68B.

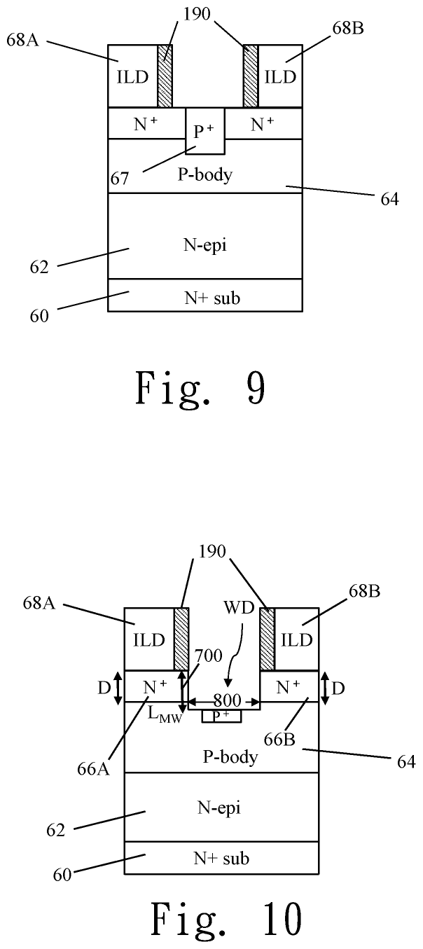

Subsequently, please refer to FIG. 9 with accompanying process step S1408 in FIG. 6, in which the present invention proceeds to provide a spacer 190, which is respectively disposed on opposite sidewalls of the first dielectric layer 68A and the second dielectric layer 68B. According to the embodiment of the present invention, a thickness of the spacer 190 can be, for example, between 0.2 Jam and 1.0 μm. In addition, the spacer 190 can be made of silicon nitride (Si₃N₄), silicon dioxide (SiO₂), nickel (Ni), or a material not removable when subsequently performing the following shallow trench process. Considering the Si₃N₄ spacer as an example, then in such a step, a Si₃N₄ hard mask layer can be deposited first. After that, an anisotropic etching process can be adopted to form a gap there in between the Si₃N₄ hard mask layer, such that Si₃N₄ sidewalls are left. As a result, the structure as illustrated in FIG. 9 of the present invention, depicted by the spacers 190 respectively disposed on opposite sidewalls of the first dielectric layer 68A and the second dielectric layer 68B is obtained.

Therefore, after the formation of the spacers 190 is complete, as shown in the step of S1410 in FIG. 6, the present invention is able to proceed to perform a shallow trench process along the opposite surfaces of the two spacers 190, such that the metal contact window WD can be downwardly extending. And by the metal contact window WD which extends downwardly along with the silicon carbide shallow trench process, it is effective to divide the above-mentioned source heavily doped area into the first heavily doped region 66A and the second heavily doped region 66B as shown in FIG. 10. At the same time, it can be found that the longitudinal surface 700 which is along the first heavily doped region 66A and the second heavily doped region 66B, as well as the interval surface 800 which is between the first heavily doped region 66A and the second heavily doped region 66B are exposed as well. In details, according to the embodiment of the present invention, the foregoing shallow trench process to be performed, for instance, can be accomplished by utilizing a plasma etching process. And in a preferrable embodiment of the present invention, it is applicable to perform the shallow trench process for etching the source heavily doped area (N-type silicon carbide) and controlling the etching depth of the shallow trench process being approximately close to or slightly more than (not less than) the thickness D of the first heavily doped region 66A and the second heavily doped region 66B, in order to expose the longitudinal surface 700 having sufficient depth L_{MW}. As a result, the depth L_{MW} of the longitudinal surface 700 can be preferably controlled between 0.2 μm and 0.5 μm.

And then, as shown in the step of S1412 in FIG. 6, the present invention is able to proceed to remove the previously used spacers 190. After the spacers 190 are removed, as we can see in FIG. 11, the first metal-source surface contact region 601 and the second metal-source surface contact region 602 can be exposed. According to one embodiment of the present invention, it is feasible to remove the spacers 190 by using hot phosphoric acid (H₃PO₄). Therefore, after the spacers 190 are removed, it effectively exposes the first metal-source surface contact region 601 and the second metal-source surface contact region 602 as required. In addition, apparently, according to the embodiment of the present invention, the length L_{MS} of the exposed first metal-source surface contact region 601 and the second metal-source surface contact region 602 can be adjusted and determined by controlling a thickness of the spacer 190. For instance, according to the disclosed fabrication process method of the present invention, when the spacer 190 has a thickness of 0.2 μm to 1.0 μm, then it results in the subsequent exposed length L_{MS} of the exposed first metal-source surface contact region 601 and the second metal-source surface contact region 602 to be 0.2 μm to 1.0 μm as well. And preferably, the thickness of the spacer 190 (corresponding to the exposed length L_{MS} of the first metal-source surface contact region 601 and the second metal-source surface contact region 602) can be 0.3 μm.

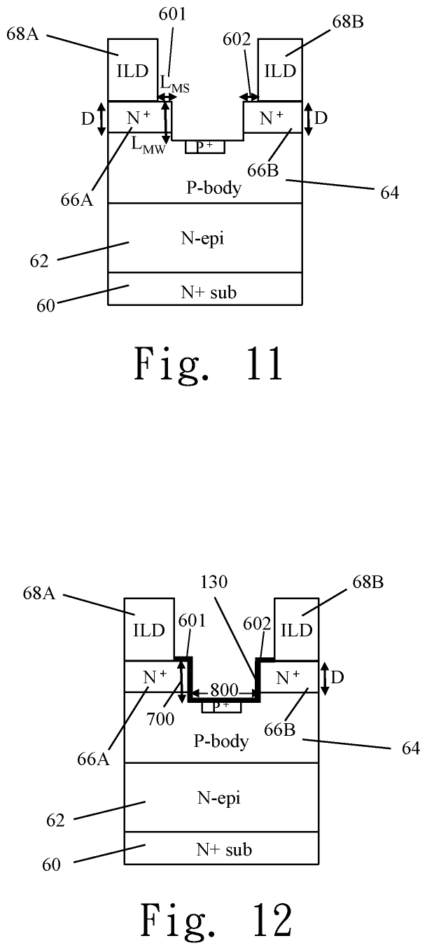

And therefore, as shown in the step of S1414 in FIG. 6, the present invention is able to proceed to deposit a source contact metal on a basis of the structure in FIG. 11, such that the source contact metal 130 as illustrated in FIG. 12 can be formed. On account of the above, the source contact metal 130 formed by employing the disclosed process method is able to cover at least the above-mentioned first metal-source surface contact region 601, the above-mentioned second metal-source surface contact region 602, the longitudinal surface 700 along the first heavily doped region 66A and the second heavily doped region 66B, and the interval surface 800 between the first heavily doped region 66A and the second heavily doped region 66B, such that the source contact metal 130 formed by the present invention has a step-like three-dimensional structure. As earlier described in the previous sections, the source contact metal 130 can be formed, for example, by depositing a contact metal first, such as nickel (Ni), and annealing it at a high temperature to form nickel-silicide (Ni-silicide). After that, a selective etching process can be carried out to remove the unreacted nickel, such that the source contact metal 130 as shown in FIG. 12 can be formed. As a result, according to the embodiment of the present invention, the source contact metal 130 formed by the present invention is characterized by having a step-like three-dimensional structure.

And in a further aspect, according to the embodiment of the present invention, when the thickness of the spacer 190 is taken as 0.3 μm, for example, then it indicates that the etching width of the contact window when performing the lithography process can be larger than that of the traditional process by 0.6 μm. As a result, it is believed that it is able to significantly enhance to reduce the difficulty and complexity of the current lithography etching process. Apart from these, when depositing the source metal, since the two spacers 190 on the sidewalls have been removed, and the enlarged contact window width can be obtained by 0.6 jam, it is also beneficial for forming the source metal having the step-like coverage and outline shape. As a result, it is obvious that by employing the process techniques of the present invention, a step-like three-dimensional source contact structure can be successfully fabricated. In addition, the cell pitch can be reduced by 0.6 to 1.0 μm under the condition of maintaining the same contact area. Meanwhile, due to the process techniques of the present invention, it also allows to have a larger contact window pattern and advantageous for contact window lithography process going on.

In the following, the Applicants of the present invention further provide a plurality of data to verify the inventive effects of the disclosed invention. Assume that a length of a JFET (Junction Field Effect Transistor) region L_{JFET} is 1.5 μm, a channel length L_{CH} is 0.5 μm, an overlap length between the gate and source regions LGS is 0.3 μm, a spacing between the gate region and contact window is 0.5 μm, a surface contact length between the metal and source region, which is the formed L_{MS} of the present invention is 0.6 μm, a contact width between the metal and P-body is 0.5 μm, a thickness of the source heavily doped area is 0.3 jam, and a cell pitch of a basic device structure is 5.8 μm. When employing the disclosed technical solutions of the present invention, it is desirable to increase the vertical contact area of the metal and source region, which is the formed L_{MS}=0.3 μm. As a result, it is apparent that a total contact length of 0.6 μm can be achieved under the condition when a surface contact length between the metal and source region is reduced to 0.3 μm. And therefore, it is believed that the present invention succeeds in reducing the cell pitch of the transistor structure by 10.3% (2*L_{MW}=0.6 μm). And if some other length parameters in the transistor structure can be reduced as well such that its cell pitch configured therein can be further scaled down to 4.0 μm, then it is also applicable to use the disclosed manners of the present invention to reduce the cell pitch by 0.6 μm. Under such circumstances, the yield for reducing cell pitch can be raised up to 15%.

Meanwhile, in view of the exposed metal-source surface contact region by 0.3 μm, which means an exposed source surface equal to 0.3 jam can be obtained, it is expected by employing the present invention, it is effective to enlarge the contact window by 0.6 μm and decrease its depth by 0.3 μm. From these points of views, it is believed that the process techniques of the present invention effectively achieve in obtaining a larger contact window pattern and also being beneficial to the following proceeding contact window lithography process. These are also some other major inventive effects of the present invention.

In another aspect, as previously described in the present invention, an outline structure of the disclosed first and second dielectric layers is not limited thereto the above-mentioned rectangle shape in the earlier embodiment. According to other alternative embodiments of the present invention, the first and second dielectric layers may also be formed into various shapes and structures by employing some other adequate etching processes. It will be apparent to those skilled in the art that various modifications and variations can be made without departing from the spirits of the invention, and still fall within the scope of the invention. To sum up, it should be obvious that the main techniques of the present invention comprise utilizing the spacers and performing the silicon carbide shallow trench process along the spacers to form the vertical contact between the metal and source region (the exposed longitudinal surface) and removing the spacers afterwards to expose the horizontal surface contact between the metal and source region (the exposed first and second metal-source surface contact regions). As a result, the proposed three-dimensional source contact structure as claimed in the present invention can be accomplished.

As a result, as set forth, it is believed that by employing the disclosed embodiments and process methods of the present invention, it achieved in effectively reducing not only the cell pitch but also the fabrication process complexity, especially under the condition that the same contact area and symmetric contact area at the left and right sides of the source region can be maintained. Therefore, the technical solutions disclosed in this application are not only advantageous in terms of process complexity and cost considerations, but also valuable in industrial applications. Among all, for people who are skilled in the art and have knowledge in the backgrounds, it should be feasible for adjustments and modifications to be made without departing from the main spirits of the application according to their actual requirements of the transistor type, electrical characteristics, channel lengths, and so on, Nevertheless, based on the equality, it is believed that these variations should still fall into the scope of the application of the present invention.

As a result, in view of the above-mentioned technical features, it is guaranteed that the present invention proposes an extremely novel and inventive process technique. Compared with the prior art, it is believed that the embodiments disclosed in the present invention and the process method thereof can effectively solve the existing deficiencies in the prior art. In addition, according to the fabrication process method disclosed in the present invention, it can be effectively applied to silicon carbide substrate, and further to any other substrate which is made of semiconductor materials, even with a wide energy gap. Apart from these, according to the fabrication process method disclosed in the present invention, it is obvious that the fabrication process method can be applied to a general Vertical Double Diffused Metal Oxide Semiconductor Field Effect Transistor (VDMOSFET) or to a general U-shaped Metal Oxide Semiconductor Field Effect Transistors (UMOSFET). Alternatively, it can be further widely applied to any power transistor which includes the VDMOSFET or the UMOSFET structure, for example, an Insulated Gate Bipolar Transistor (IGBT), such that a three-dimensional source contact structure can be made therein. As a result, the Applicants assert that the present invention is instinct, effective and highly competitive for the incoming technologies, industries and researches developed in the future. And since the technical features, means and effects achieved by the present invention are significantly different from the current solutions and can not be accomplished easily by those who are familiar with the industry, it is thus believed that the present invention is indeed characterized by patentability and shall be patentable soon in a near future.

It is worth reminding that the present invention is not limited to the above-mentioned process layouts. In other words, those skilled in the art are able to make equivalent modifications and variations based on their actual product specifications. And yet, it is believed that such modified embodiments should still fall within the scope of the present invention.

It will be apparent to those skilled in the art that various modifications and variations can be made to the present invention without departing from the scope or spirit of the invention. In view of the foregoing, it is intended that the present invention cover modifications and variations of this invention provided they fall within the scope of the invention and its equivalent.

What is claimed is:

1. A three-dimensional source contact structure applicable to a power device, wherein the power device includes a semiconductor substrate, an epitaxial layer and a body region are sequentially formed on the semiconductor substrate, and the three-dimensional source contact structure comprises:
a source heavily doped area configured on the body region, wherein a metal contact window is formed in the source heavily doped area, such that the source heavily doped area is divided by the metal contact window into a first heavily doped region and a second heavily doped region formed on opposite sides of the metal contact window;
an inter-layer dielectric configured on the source heavily doped area, wherein the inter-layer dielectric is also divided by the metal contact window into a first dielectric layer and a second dielectric layer formed on opposite sides of the metal contact window, the first dielectric layer is disposed on the first heavily doped region, the second dielectric layer is disposed on the second heavily doped region, and wherein a contact length of the first dielectric layer and the first heavily doped region is less than a length of the first heavily doped region such that a first metal-source surface contact region is exposed, and wherein a contact length of the second dielectric layer and the second heavily doped region is less than a length of the second heavily doped region such that a second metal-source surface contact region is exposed; and
a source contact metal being deposited between the first dielectric layer and the second dielectric layer, between the first heavily doped region and the second heavily doped region, and on the body region though the metal contact window, wherein the source contact metal covers at least the first metal-source surface contact region, the second metal-source surface contact region, a longitudinal surface along the first heavily doped region and the second heavily doped region, and an interval surface between the first heavily doped region and the second heavily doped region, such that the source contact metal has a step-like three-dimensional structure.

2. The three-dimensional source contact structure according to claim 1, wherein a length of the first metal-source surface contact region and the second metal-source surface contact region is between 0.2 μm and 1.0 μm.

3. The three-dimensional source contact structure according to claim 1, wherein a depth of the longitudinal surface along the first heavily doped region and the second heavily doped region is between 0.2 μm and 0.5 μm.

4. The three-dimensional source contact structure according to claim 1, wherein the semiconductor substrate is made of silicon (Si), silicon carbide (SiC), gallium oxide (Ga₂O₃), aluminum nitride (AlN), or diamond.

5. The three-dimensional source contact structure according to claim 1, wherein the power device includes a Vertical Double Diffused Metal Oxide Semiconductor Field Effect Transistor (VDMOSFET), and the step-like three-dimensional structure is applicable to the source contact metal of the VDMOSFET.

6. The three-dimensional source contact structure according to claim 1, wherein the power device includes an U-shaped Metal Oxide Semiconductor Field Effect Transistor (UMOSFET), and the step-like three-dimensional structure is applicable to the source contact metal of the UMOSFET.

7. The three-dimensional source contact structure according to claim 1, wherein a third heavily doped region is formed underneath the metal contact window, and the third heavily doped region is buried in the body region.

8. The three-dimensional source contact structure according to claim 7, wherein a width of the third heavily doped region is alternatively greater than a bottom width of the metal contact window.

9. The three-dimensional source contact structure according to claim 7, wherein the semiconductor substrate, the epitaxial layer, the first heavily doped region and the second heavily doped region have a first semiconductor type, the body region and the third heavily doped region have a second semiconductor type, and the first semiconductor type and the second semiconductor type are opposite conductivity types.

10. The three-dimensional source contact structure according to claim 1, wherein a material of the source contact metal comprises Ni-silicide.

11. The three-dimensional source contact structure according to claim 1, wherein each of the first dielectric layer and the second dielectric layer is formed in a rectangle shape.

12. A fabrication process method of making the three-dimensional source contact structure according to claim 1, comprising:
providing the power device which includes the semiconductor substrate, the epitaxial layer and the body region sequentially formed on the semiconductor substrate;
forming the source heavily doped area on the body region, wherein a third heavily doped region is buried in the body region, and the third heavily doped region is configured and isolated in the source heavily doped area;
depositing the inter-layer dielectric on the source heavily doped area, and performing a lithography process to form the metal contact window and to divide the inter-layer dielectric into the first dielectric layer and the second dielectric layer;
providing a spacer respectively on opposite sidewalls of the first dielectric layer and the second dielectric layer;
performing a shallow trench process along opposite surfaces of two of the spacers to divide the source heavily doped area into the first heavily doped region and the second heavily doped region through the metal contact window which extends downwardly, and exposing the longitudinal surface along the first heavily doped region and the second heavily doped region and the interval surface between the first heavily doped region and the second heavily doped region;
removing the spacers to expose the first metal-source surface contact region and the second metal-source surface contact region; and
depositing the source contact metal between the first dielectric layer and the second dielectric layer, between the first heavily doped region and the second heavily doped region, and on the body region, wherein the source contact metal covers at least the first metal-source surface contact region, the second metal-source surface contact region, the longitudinal surface along the first heavily doped region and the second heavily doped region, and the interval surface between the first heavily doped region and the second heavily doped region, such that the source contact metal has the step-like three-dimensional structure.

13. The fabrication process method according to claim 12, wherein the shallow trench process is performed by a plasma etching process.

14. The fabrication process method according to claim 12, wherein an etching depth of the shallow trench process is not less than a thickness of the first heavily doped region and the second heavily doped region to expose the longitudinal surface along the first heavily doped region and the second heavily doped region.

15. The fabrication process method according to claim 12, wherein the spacer is made of silicon nitride (Si₃N₄), silicon dioxide (SiO₂), nickel (Ni), or a material not removable when performing the shallow trench process.

16. The fabrication process method according to claim 12, wherein a thickness of the spacer is between 0.2 μm and 1.0 μm.

17. The fabrication process method according to claim 12, wherein a depth of the longitudinal surface along the first heavily doped region and the second heavily doped region is between 0.2 μm and 0.5 μm.

18. The fabrication process method according to claim 12, wherein a width of the third heavily doped region is alternatively greater than a bottom width of the metal contact window.

19. The fabrication process method according to claim 12, wherein each of the first dielectric layer and the second dielectric layer is formed in a rectangle shape.

20. The fabrication process method according to claim 12, wherein the power device includes a Vertical Double Diffused Metal Oxide Semiconductor Field Effect Transistor (VDMOSFET) or an U-shaped Metal Oxide Semiconductor Field Effect Transistor (UMOSFET), and the step-like three-dimensional structure is applicable to the source contact metal of the VDMOSFET or the UMOSFET.

21. The fabrication process method according to claim 12, wherein the spacers are removed by using hot phosphoric acid (H₃PO₄).
